(19) United States
(12) Patent Application Publication
(10) Pub. No.: US 2009/0058686 A1
(43) Pub. Date: Mar. 5, 2009

(54) Isotonic/elastic hybrid input device

(75) Inventors: Christophe Chaillou, Lille (FR); Gery Casiez, Honnechy (FR)

Correspondence Address: HARNESS, DICKEY & PIERCE, P.L.C., P.O. BOX 828, BLOOMFIELD HILLS, MI, 48303, US

(73) Assignee: UNIVERSITÉ DES SCIENCES ET TECHNOLOGIES DE LILLE, Villeneuve d'Ascq Cedex (FR)

(21) Appl. No.: 11/919,807

(22) PCT Filed: May 2, 2006
(86) PCT No.: PCT/EP2006/004078

§ 371 Date: Nov. 2, 2007

(30) Foreign Application Priority Data
May 4, 2005 (EP) 05370010.0

(51) Int. Cl. H03K 17/94

(52) U.S. Cl. 341/20

(57) ABSTRACT

The absolute input device with passive force feedback comprises a mobile end-effector (5) in a work area that is divided into at least two distinct adjacent areas: one isotonic area (I) and one passive elastic area (E).

### TECHNICAL FIELD

The present invention relates to absolute input devices with passive force feedback and designed to be used in the computing field as pointing devices or for manipulating objects in a virtual environment.

### PRIOR ART

The computer input devices that are used as pointing devices or for manipulating virtual objects may be classified in three categories (isotonic, isometric or elastic) according to the mobility and the degree of resistance exerted on their end-effector.

In an isotonic device, the end-effector moves freely and may be displaced with no resistance or with constant and very low resistance.

In an isometric device (also called a force or pressure device), the end-effector is not mobile or is practically not mobile, and the force applied on the end-effector and transmitted by the latter is measured physically.

In an elastic device, the end-effector is mobile but the resistance on the end-effector increases with the displacement.

Isotonic input devices may also be classified into two families: absolute devices or relative devices.

In an absolute device, the end-effector is mechanically connected to a fixed support and is mobile with relation to this support in a real physical work space, hereafter designated as the “work area” of the end-effector. An absolute device transmits a position (x), (x,y) or (x,y,z) measured in a framework of the work area. In this type of device, the dimension of the virtual environment is limited by the size of the work area of the end-effector.

An end-effector clutch mechanism is provided in the case of absolute devices (end-effector mobile with relation to its support according to one, two, or three degrees of freedom) to increase the size of the virtual environment. Said mechanism is for example activated by means of a button or by limit switches such as in international patent application WO 2004/001577. However, this end-effector clutch is not intuitive for the user, and thus proves to be not very practical.

Relative devices comprise an end-effector that, as distinguished from absolute devices, is free, i.e. is not mechanically connected to a fixed support. Relative devices are necessarily devices with one or two dimensions and send position increments (dx) or (dx, dy). The most popular isotonic and relative computer input device to date is the device commonly referred as a “mouse.” In a one-dimensional or two-dimensional relative device, the end-effector (mobile part) not being mechanically connected to a support, it may advantageously be easily and intuitively released from its real physical environment (work area), which allows a large distance in a virtual space to be covered without having to significantly displace the end-effector in its work area. In the case of a mouse, this clutch is obtained simply by lifting the mouse. With a one-dimensional or two-dimensional relative device, the size of the virtual environment is therefore not limited by the dimension of the end-effector work area.

Computer input devices may also be distinguished by whether they are passive or active force feedback devices.

Active force feedback input devices, also designated as haptic devices, comprise one or more actuator that are controlled by an electrical signal in such a way as to apply a force feedback on the input device end-effector that is calculated according to a predefined law from the position or displacement of the end-effector. This active force feedback allows, for example, the user manipulating the end-effector to feel constraints (for example, an obstacle that is more or less hard) in the virtual environment in which the virtual object that is controlled by means of the input device moves. An active force feedback input device is of the absolute type since it is necessary to provide mechanical connections to transmit forces to the end-effector. These active force feedback input devices are particularly widely used in the field of video games in the form of, for example, an active force feedback handle. An active force feedback absolute haptic device presenting three independent degrees of freedom is for example described in European patent application EP 1 437 641.

The actuators of these haptic devices first are voluminous and bulky and secondly are expensive, which today makes them unsuitable for making miniature computer input devices at a very low cost. Furthermore, in numerous applications, the implementation of active force feedback has proved to be unnecessary.

To make a computer input device at a very low cost and that is very small, passive force feedback devices are used today. These passive force feedback devices are of the isotonic, isometric or elastic type.

More particularly, in the case of isotonic devices, in order to expand the dimension of the virtual space, relative devices are used such as for example a mouse or a miniature device comprising a touch-sensitive pointing device that is integrated with a keypad, particularly a portable computer keypad, and which is commonly designated as a “touchpad.” “Touchpad” type input devices are described in, for example American patents U.S. Pat. No. 5,521,336, U.S. Pat. No. 4,529,959 and U.S. Pat. No. 4,455,450.

A popular example of a miniature isometric input device integrated with a keypad is a miniature “joystick” of the type of that described in American patent U.S. Pat. No. 5,541,622.

### OBJECTIVES OF THE INVENTION

A general objective of the invention is to propose a new passive and absolute type force feedback input device (i.e. a device whose end-effector is mechanically connected to a support and is mobile with relation to this support).

A more particular objective of the invention is to propose a new passive force feedback absolute input device that allows, without implementing an end-effector clutch mechanism, the dimension of the virtual space to be increased compared to an absolute isotonic device that has the same geometry for the end-effector work area.

Another more particular objective of the invention is to propose a new absolute input device that presents very low bulkiness, and preferably that may be integrated with a keypad or similar device and/or that presents a low manufacturing cost [which excludes active (haptic devices) force feedback solutions].

### SUMMARY OF THE INVENTION

The solution of the invention is based on the implementation of an absolute input device with a hybrid (isotonic/elastic) type passive force feedback, such as defined in claim 1.

This absolute input device with passive force feedback comprises a mobile end-effector in a work area. Said work area is divided into at least two distinct adjacent areas: an isotonic area and a passive elastic area.

The terms “passive elastic area” means any area wherein a passive elastic force is applied on the end-effector, said passive elastic force being opposed to the displacement of the end-effector (without blocking it), and having an intensity that increases with the distance of penetration of the end-effector in the elastic area.

Within the scope of the invention, the absolute input device of the invention may be a device whose end-effector is mechanically connected to a fixed support and being mobile with relation to this support in one dimension (work axis) or in two dimensions (work surface) or in three dimensions (work volume).

More particularly, but in a non-limiting manner for the scope of the invention, an elastic area might present additional and optional characteristics hereafter mentioned and taken alone or if necessary in combination with each other:

a passive elastic area (E) comprises at least one spring;

a passive elastic area (E) comprises an elastic stop (for example a casing, cushion or the like) filled with a fluid (gas, liquid) and is elastically deformable by the end-effector;

a passive elastic area (E) comprises an elastic stop made of a material that is elastic and elastically deformable by the end-effector;

the passive elastic area (E) is obtained by using an elastic stop that is mobile with the end-effector.

### BRIEF DESCRIPTION OF THE FIGURES

Other characteristics and advantages of the invention will appear more clearly upon reading the detailed description of several preferred embodiments of a hybrid absolute input device of the invention, which description is given by way of non-limiting and non-exhaustive example of the invention, and with reference to the attached drawings in which:

FIG. 1 is a diagram illustrating the means (known from the prior art) implemented to control a virtual environment with the aid of an absolute input device;

FIG. 2 is a representation in perspective of a first embodiment of a hybrid device of the invention (1D hybrid device);

FIG. 3 is a wireframe representation of the device from FIG. 2;

FIG. 4 is a partial view of the device from FIG. 2 showing the detection and coding means of the end-effector position;

FIG. 5 is a perspective representation of a second embodiment of a hybrid device of the invention (2D hybrid device);

FIG. 6 is a wireframe representation of the device from FIG. 5;

FIG. 7 is a partial transverse cross sectional view of the device from FIG. 5;

FIG. 8 is a perspective representation of a third embodiment of a hybrid device of the invention (2D hybrid device);

FIG. 9 is a wireframe representation of the device from FIG. 8;

FIG. 10 is a partial transverse cross sectional view of the device from FIG. 8;

FIG. 11 is a perspective representation of a fourth embodiment of a hybrid device of the invention (2D hybrid device);

FIG. 12 is a perspective representation of a fifth embodiment of a 3D hybrid device of the invention;

FIG. 13 is a schematic representation of a sixth embodiment of a 2D hybrid device of the invention.

### DETAILED DESCRIPTION

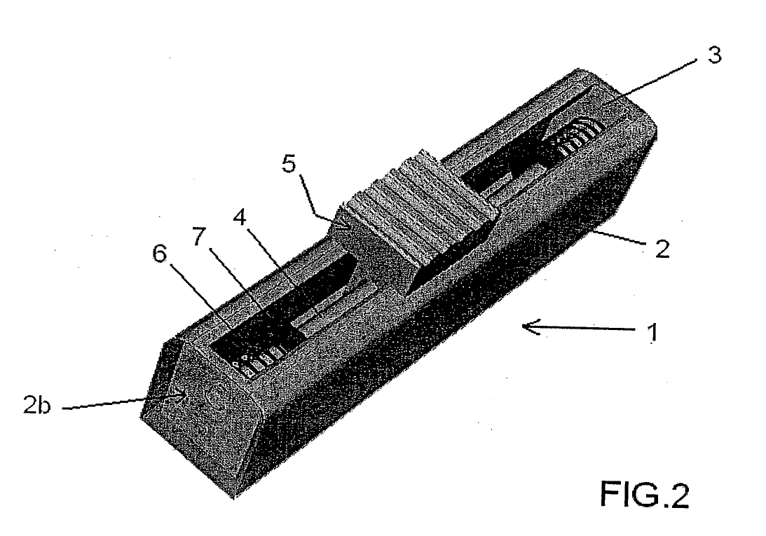

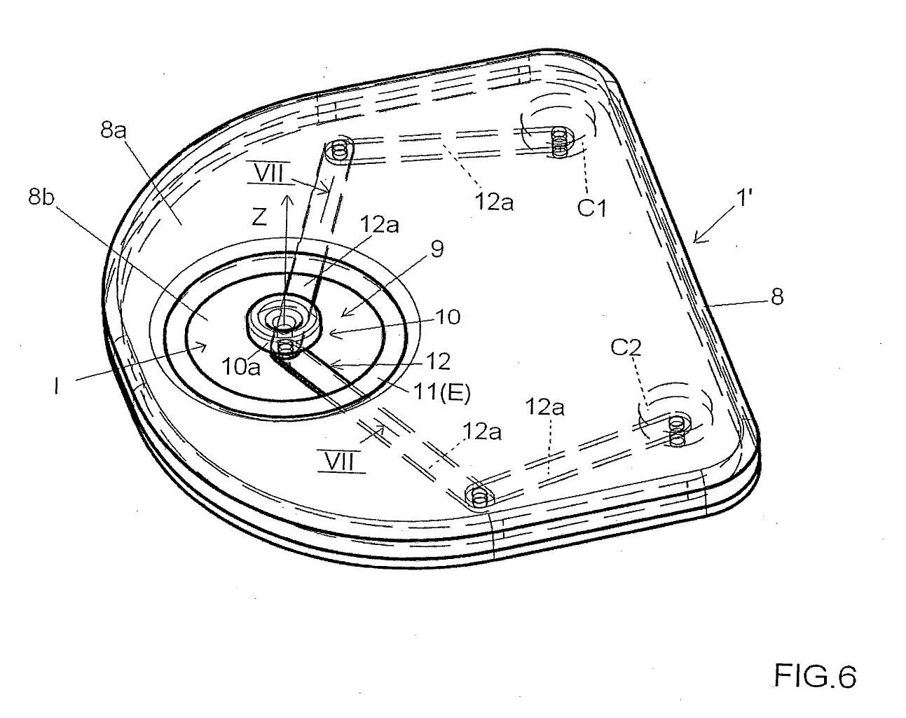

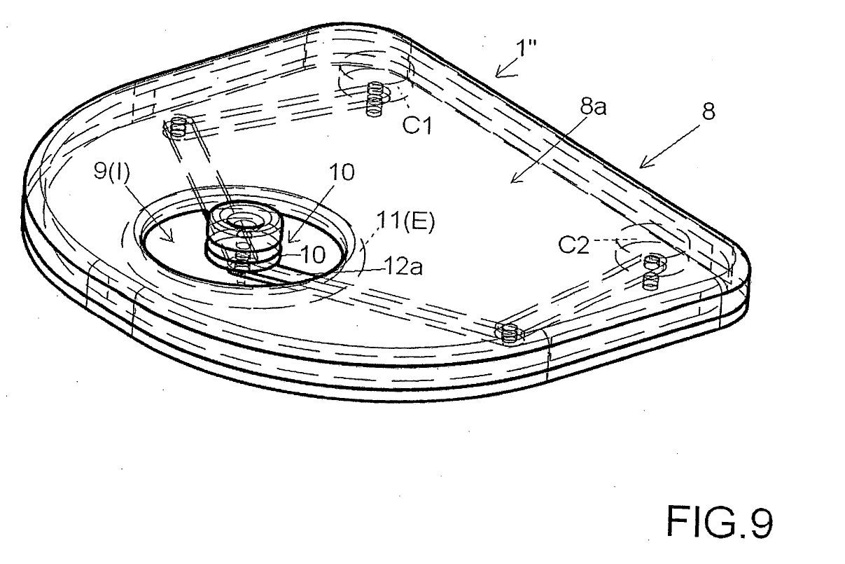

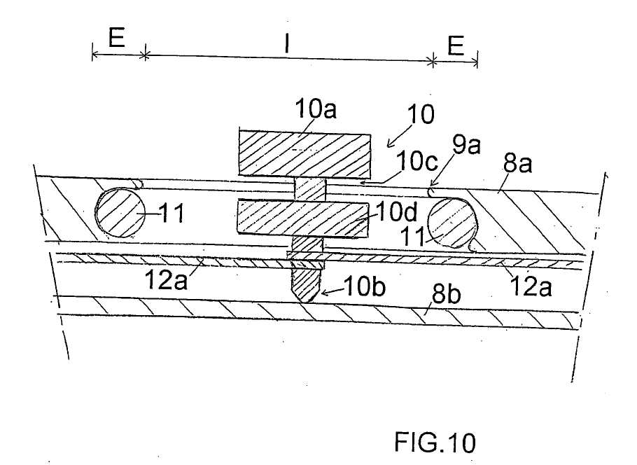

Several embodiments of an absolute and hybrid (isotonic/elastic) input device in conformance with the invention are represented in FIGS. 2 to 12.

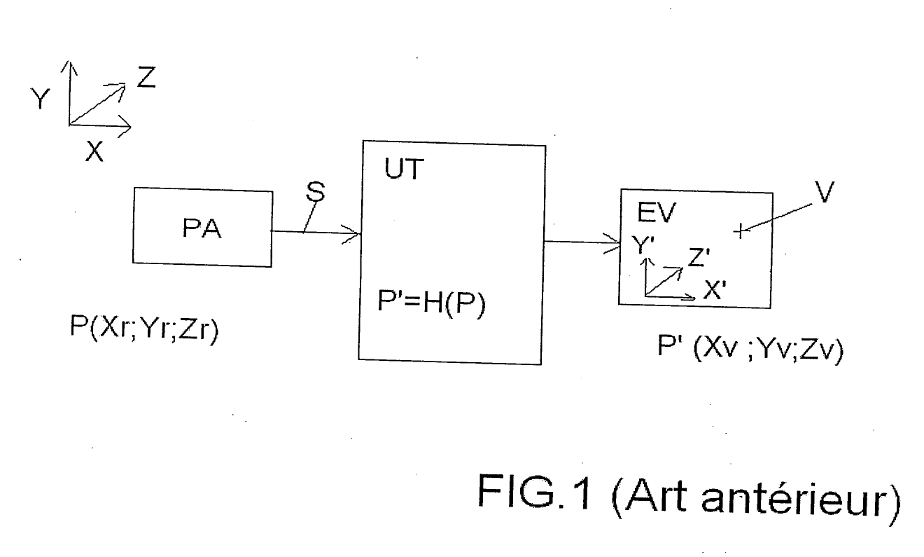

### FIG. 1/Generalities on Absolute Input Devices

Prior to the detailed description of these embodiments and with reference to FIG. 1, it should briefly be said that in a manner that is known by one skilled in the art, an absolute input device (PA), either of the isotonic or elastic type, is designed to be connected to a programmed process unit (UT) (for example, a central unit of a microcomputer). The absolute input device (PA) comprises an end-effector that is mobile in a real space (X, Y, Z) and that is connected mechanically to this real space, and means for detecting the instantaneous position (p) of the end-effector in this real space.

Coordinates (xᵣ, yᵣ, zᵣ) of the real instantaneous position of the end-effector are sent to or read by the process unit (UT) [FIG. 1/signal S]. The process unit (UT) executes a program for managing a virtual environment (EV) that is dynamically displayed on a screen. This virtual environment (EV) contains, for example, a virtual (V) object associated with the end-effector of the device (PA).

The virtual environment (EV) management program maps, at the real instantaneous position p(xᵣ, yᵣ, zᵣ) of the end-effector, a unique virtual instantaneous position p′(xᵥ, yᵥ, zᵥ) in a virtual space (X′, Y′, Z′) of the virtual environment (EV), by means of a predefined transfer function H: p′(xᵥ, yᵥ, zᵥ)=H[p(xᵣ, yᵣ, zᵣ)]; this is, for example, the position of the virtual object (V).

It must be emphasized that the real space (X, Y, Z) and the virtual space (X′, Y′, Z′) are not necessarily three-dimensional spaces (displacement of the end-effector in a volume of work), but may be two-dimensional spaces (displacement of the end-effector on a work surface) or one-dimensional spaces (displacement of the end-effector according to a unique work axis). Moreover, the real space (X, Y, Z) and the virtual space (X′, Y′, Z′) are not necessarily orthonormal.

When the order of transfer function (H) is equal to 0, the relationship between the input parameter (p) and the output parameter (p′) is a simple relationship of proportionality. The displacement measured on the end-effector of the input device (PA) is translated in the virtual environment (EV) by a displacement in the virtual environment (VE). One then speaks of position control.

In the case of a transfer function H whose order is equal to 0 (position control), the vector h (hₓ, h_{y}, h_{z}) connecting the real space (X, Y, Z) and the virtual space (X′, Y′, Z′) is designated in the rest of the description by the wording “homothetic ratio”, and is defined by the following relationship:

$$[ \begin{matrix}{x}_{v} \\ {y}_{v} \\ {z}_{v}\end{matrix} ] = [ \begin{matrix}{h}_{x} \\ {h}_{y} \\ {h}_{z}\end{matrix} ] \times [ \begin{matrix}{x}_{r} \\ {y}_{r} \\ {z}_{r}\end{matrix} ]$$

The transfer function (H) may also have in some applications a order equal to 1. When the order of the transfer function (H) is equal to 1, the relationship between the input parameter (p) and the output parameter (p′) is of the integral type; in this case, the displacement measured on the end-effector of the input device (PA) is interpreted in terms of speed in the virtual environment (EV). One then talks of speed control.

In practice, isotonic devices are better adapted to transfer functions having a order equal to 0, and isometric devices or elastic devices are better adapted to transfer functions having a order equal to 1.

### One-Dimensional Hybrid (Isotonic/Elastic) Absolute Device—FIGS. 2 to 4

FIGS. 2 to 4 represent a one-dimensional absolute input computer device 1 in conformance with the invention. This device 1 comprises a fixed housing 2 wherein the upper side 2a is equipped with a rectilinear slot or opening 3 along the longitudinal axis 3a.

Inside the housing 2 is mounted a fixed guiding rod 4, that extends parallel to the longitudinal axis 3a.

On this rod 4 is mounted, in a sliding manner, an end-effector 5 having a unique degree of freedom in translation in a direction parallel to axis 3a. Rod 4 allows the end-effector 5 to be guided in translation in said direction parallel to longitudinal axis 3a.

More particularly, in the example illustrated, the end-effector 5 is made in the form of a digital cursor 5a comprising or integral with a base 5b that passes through the longitudinal slot 3 and which is threaded on the rod 4 in such a way as to be able to slide along this rod 4.

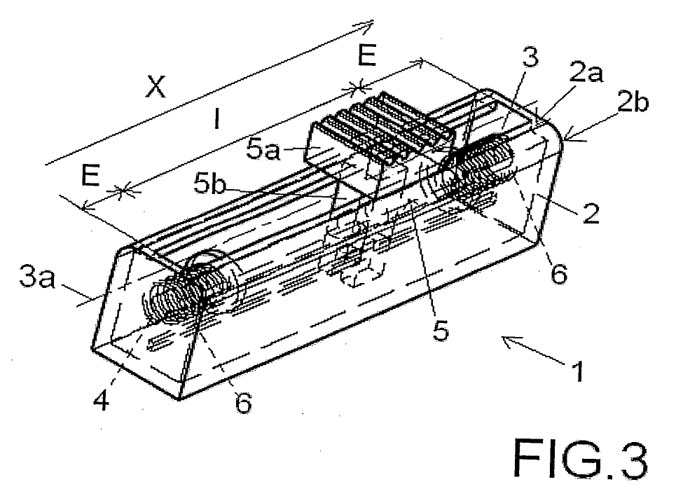

On each extremity of the rod 4 is mounted a spring 6 associated with a washer 7 that is threaded onto the rod 4 and that is able to slide along this rod 4. The spring 6 is positioned between said washer 7 and the lateral side of extremity 2b of the housing 2. The washer 7 is preferably, but not necessarily, fixed to the spring 6. The extremity of the spring 6 in contact with the lateral side 2b may possibly, but not necessarily, be fixed to said lateral side 2b. In FIGS. 2 and 3, the two springs 6 are represented in the relaxed state.

This input device comprises a central isotonic work area (I) having one dimension and oriented in a direction parallel to the longitudinal axis 3a. Said isotonic work (I) extends between the two opposing faces of the two washers 7 in their rest position, i.e. in their position of FIG. 3 wherein the two springs 6 are not compressed.

At each extremity of the central isotonic area (I), the input device comprises an extreme elastic work area (E), that is oriented in a direction parallel to the longitudinal axis 3a, and that is adjacent to the central isotonic area (I).

In the particular example illustrated, each elastic work area (E) extends between a washer 7 in its rest position and the nearest extremity of the longitudinal slot 3.

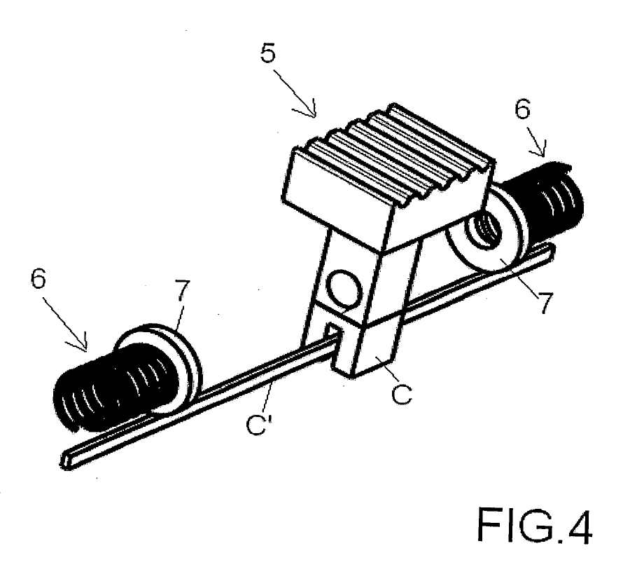

With reference to FIG. 4, the device 1 furthermore comprises means for detecting (C, C′) the instantaneous position (xᵣ) of the end-effector 5 along an axis (X) that is parallel to the longitudinal axis 3a, said detection means delivering an electrical signal for coding this instantaneous position.

In the particular embodiment of FIG. 4, these detection means are constituted by two parts: a mobile optical sensor C provided at the base of the end-effector 5; a fixed part in the form of a transparent band or strip C′, which is parallel to the axis of displacement of the end-effector 5 and which crosses through the mobile sensor C. On the transparent band or strip C′ are drawn marking lines or equivalent (not visible in FIG. 4). In operation, the mobile optical sensor C detects the presence or absence of marking lines, and delivers an electrical signal allowing the position of the end-effector 5 on the rod 4 to be coded. The sensor C being a relative sensor, one has to perform an initialization phase during which the end-effector 5 is for example displaced against one of the washers of the elastic stop 7.

In another embodiment, the detection and coding means of the end-effector position may also be made of a slide potentiometer coding the absolute position of the end-effector 5 on the rod 4.

In operation, when the end-effector 5 is positioned in the isotonic (I) area, a user may cause it to freely slide in this area (I) without the end-effector 5 undergoing force opposed to its displacement (with the exception of low frictional forces on the rod 4 which are negligible). When the end-effector 5 reaches the limit of the isotonic (I) area, and penetrates in one of the two elastic (E) areas, the corresponding spring exerts an elastic feedback force through the washer 7 according to the longitudinal axis 3a that is opposed to the displacement of the end-effector 5. The standard (F) of this force is given by the relationship: F=k.x′ᵣ

### Where:

x′ᵣ represents the distance of penetration (from the isotonic area (I)) of the end-effector 5 in the elastic area (E), i.e. in the example illustrated the distance according to the longitudinal axis X between the instantaneous position xᵣ of the end-effector 5 and the initial position at rest of the washer 7, and

k is the stiffness of the spring.

When the end-effector 5 penetrates in the elastic area (E), the corresponding spring 6 is compressed. The more the end-effector 5 penetrates in the elastic area (E), the more the spring 6 is compressed and the more the elastic feedback force exerted by this spring 6 on the end-effector 5 increases.

Preferably, the transfer function (H_{E}) implemented in the elastic area (E) for controlling the virtual environment associated with device 1 from the instantaneous position xᵣ of the end-effector 5 (see above—FIG. 1/Generalities on absolute input devices) is different from the transfer function (H_{I}) implemented in the isotonic area (E).

For example, the order of the transfer function (H_{E}) is equal to 1 (speed control) and the order of the transfer function (H_{I}) is equal to 0 (position control).

### Two-Dimensional Hybrid (Isotonic/Elastic) Absolute Device

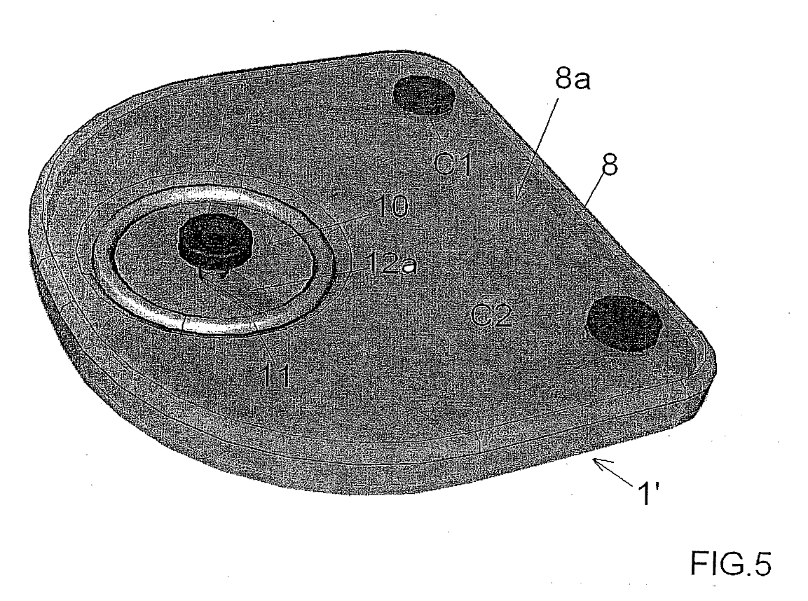

### 1^{st} Embodiment/FIGS. 5 to 7

FIGS. 5 to 7 represent a first embodiment of a two-dimensional absolute input device 1′ in conformance with the invention. This device 1′ comprises a fixed and flat housing 8, whose upper side 8a is equipped with a circular opening 9 with a small diameter, and an end-effector 10.

On the peripheral edge of the circular opening 9 is fixed an elastic torus 11 in an annular shape. This torus 11 is for example an air chamber made of an air-filled hermetic cushion or a ring made of an elastically deformable foam type material. The central area of the circular opening 9 delimited by the elastic torus 11 comprises an isotonic (I) work area, which in the example illustrated has the shape of a disk. The torus 11 delimits an elastic (E) peripheral work area, which in the example illustrated is in the shape of a ring.

The end-effector 10 is made of a handle 10a with a small size (preferably sized for digital activation) that is positioned through opening 9 and that is mechanically connected to the housing 8 by a connection system 12.

In the particular example illustrated, this connection system 12 comprises links 12a articulated between each other in such a way as to form a pantograph. This pantograph 12 allows movement in translation of the end-effector 10 in a work plane that is parallel to the planes of the links 12a. Also, in order to guarantee the displacement of the end-effector 10 only in a work plane, the base 10b of the end-effector 10 is in sliding or rolling contact with the bottom side 8b of the housing 8. This bottom side 8b forms for the end-effector, at least in an area in line with the circular opening 9, a flat guiding surface that is parallel to the plane of the pantograph 12. Therefore, risks of displacing the end-effector 10 toward the inside of the housing 8 according to the Z axis perpendicular to the work plane of the end-effector is avoided, particularly when the user manipulates the end-effector by exerting too much pressure.

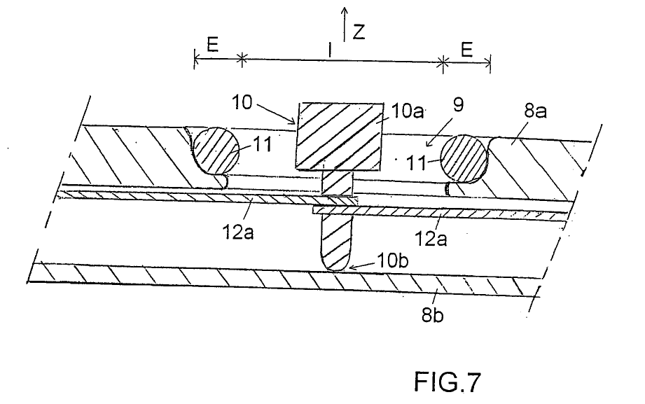

One is also assured that the friction between the end-effector 10 and the bottom side 8b of the housing is very low in order to obtain an operation in isotonic mode in the central work area (I). This is obtained by a reduced sizing of the contact region between the end-effector 10 and the bottom side 8b (for example part 10b of the end-effector 10 in contact with the bottom side 8b in a rounded shape such as illustrated in FIG. 7 in the shape of a point) and/or by providing an antifriction bearing (ball or the like) between the end-effector 10 and the bottom side 8b.

Detection of the instantaneous position p(xᵣ, yᵣ) of the end-effector 10 in the two-dimensional work area (in the central isotonic area (I) or in the elastic peripheral area (E)) is carried out by means of two sensors (C1) and (C2) measuring the instantaneous position in rotation of each extreme link 12a of the pantograph (link at the junction with the housing).

In operation, when the end-effector 10 is positioned in the central isotonic area (I), a user may cause it to slide freely in this area (I) without the end-effector 10 undergoing forces opposed to its displacement (with the exception of low friction forces that are negligible). When the end-effector 10 reaches the limit of the isotonic area (I), and penetrates in the elastic peripheral area (E), the elastic torus 11 (air chamber or ring in an elastically deformable material) corresponding to this elastic area (E) exerts a reverse elastic feedback force that is opposed to the displacement of the end-effector 10, and which increases with the radial distance of penetration of the end-effector 10 in the elastic area (E). This elastic force is a function of the inflation pressure in the case of an air chamber 11 or mechanical properties intrinsic to the elastic material in the case of a ring 11 in an elastic material.

The air in the chamber 11 may in a more general manner be replaced by any suitable fluid (gas or liquid) allowing an elastic area to be formed (E).

The considerations and disclosures on the transfer functions H_{I} and H_{E} given previously for the one-dimensional embodiment of FIGS. 2 to 4 are transposable and also apply to the two-dimensional embodiment that have just been described with reference to FIGS. 5 to 7.

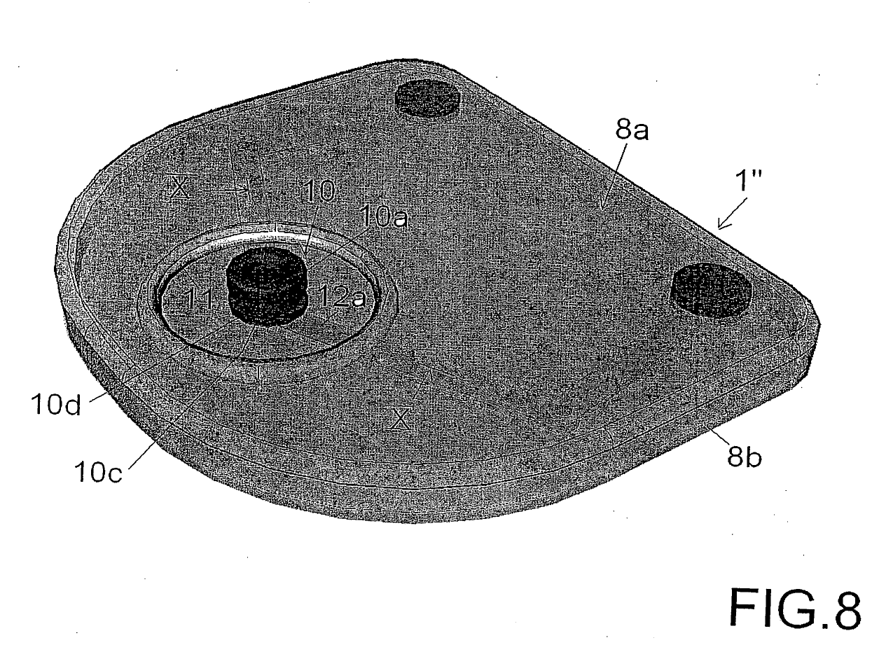

### 2^{nd} Embodiment/FIGS. 8 to 10

The device 1″ from FIGS. 8 to 10 is differentiated from the aforementioned embodiment from FIGS. 5 to 7 in that the elastic torus 11 is not visible through the circular opening 9, but is fixed under the upper side of the wall 8a of the housing 8 and is flush with the circular edge 9a of the opening 9. In order to allow contact between the end-effector 10 and the elastic torus 11, an annular recess 10c or equivalent is provided in the end-effector. This recess 10c is slightly oversized with relation to the thickness of the upper wall 8a of the housing 8 in such a way as to allow passage of the underlying part 10d of the end-effector 10 in the elastic area (E) delimited by the torus 11 beyond the circular edge 9a of the opening 9.

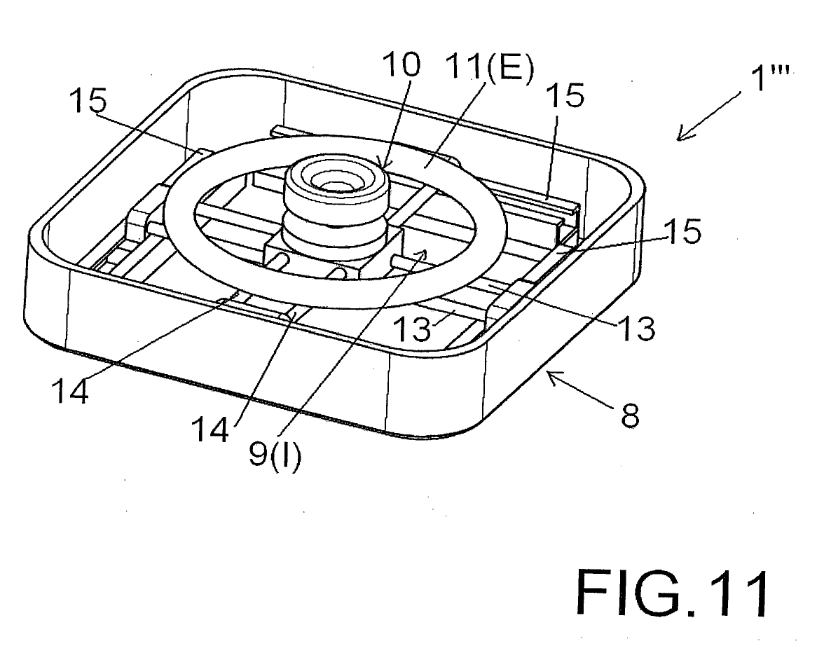

### 3^{rd} Embodiment/FIG. 11

FIG. 11 represents a third embodiment of a two-dimensional absolute input device 1″, in conformance with the invention. This device 1″ is differentiated from the aforementioned embodiment from FIGS. 8 to 10 mainly by the structure of the kinematic chain implemented to mechanically connect the end-effector 10 to the housing 8. In FIG. 11, for a better visualization of the mechanical means connecting the end-effector 10 to the housing 8, the upper side of the housing 8 (on which the elastic torus 11 is fixed) is not represented.

In this embodiment, the end-effector 10 is mounted in a sliding manner on a pair of parallel rods 13 and on a pair of parallel rods 14, the rods 13 being orthogonal to the rods 14, in such a way that the end-effector 10 is guided in translation in a plan according to the two orthogonal axes. The rods 13 and 14 are guided in translation at their two extremities in a direction perpendicular to their longitudinal axis by being mounted in a sliding manner in the rails 15 that are fixed in the bottom of the housing 8. At an extremity of each pair of rods 13 or 14 is mounted a linear sensor (for example, an optical sensor) allowing the position of the rods with relation to the fixed rail 15 to be coded.

In all aforementioned embodiments, the device 1, 1′, 1″ or 1′″ may advantageously be of a very small size. For example and in a non-limiting manner of the invention for the one-dimensional device 1′, the cumulative length of the isotonic work areas (I) and elastic (E) work areas may be less than 3 cm and for the two-dimensional devices 1′, 1″ and 1′″, the cumulative surface of the isotonic (I) work areas and elastic (E) work areas may be less than 10 cm². The miniaturization of the device of the invention may particularly be easily integrated with another device (for example a computer keypad or joystick).

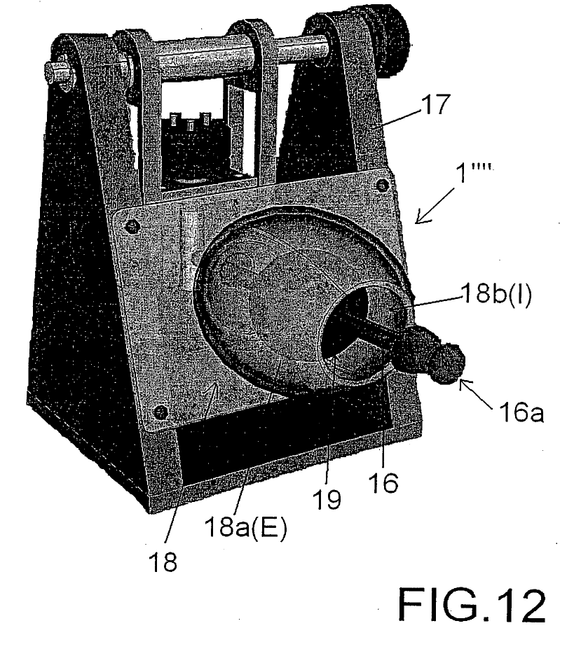

### 3D Embodiment/FIG. 12

The three-dimensional device 1″″ of FIG. 1 is made from a known 3D base device that is described in detail in the article “The DigiTracker, a Three Degrees of Freedom Pointing Device,” F. Martinot, P. Plenacoste & C. Chaillou, Eurographics Symposium on Virtual Environments (2004).

With reference to FIG. 12, it should be simply and briefly said that this known 3D base device comprises an arm 16 whose free extremity 16a is able to be manipulated by a person and forms an end-effector with three degrees of freedom. This arm is mechanically connected to a base 17 and is mobile with relation to this base 17 with three degrees of freedom. For a more complete understanding of the structure and operation of this base device, and particularly of the mobile arm 16, the associated mechanical connection means and the means for detecting and coding the position in space of this arm, the person skilled in the art may refer to this publication.

The 3D base device described in the aforementioned publication is modified in the following manner.

On the base 17 is fixed a hollow ovoid 18 (ellipsoid of revolution), constituted by a casing 18a filled with a fluid (for example air) or made of an elastic material. Furthermore, on the arm 16 is fixed a sphere 19 in a rigid material (for example in plastic or metal). This sphere 19 is positioned and is mobile inside the ovoid 18. The casing 18a of the ovoid 18 forms an elastic 3D stop at the displacement of the sphere 19, and the inner volume 18b forms an isotonic volume (I) in which the free extremity 16a (end-effector) of the mobile arm 16 may be freely displaced according to three degrees of freedom.

More particularly, the ovoid 18 in combination with the sphere 19 delimits for the end-effector (free extremity 16a of the arm) a work volume 18b that is isotonic and spherical.

In operation, during displacement of the arm 16, the sphere 19 is displaced inside the ovoid 18 in the isotonic volume 18b; when the sphere 19 enters in contact with the elastic wall 18a of the ovoid 18, this elastic wall 18a exerts on the sphere 19 elastic feedback forces whose intensity increases with the distance of penetration of the sphere in the wall 18a of the ovoid 18, and which are oriented radially in the direction of the center of the sphere 19.

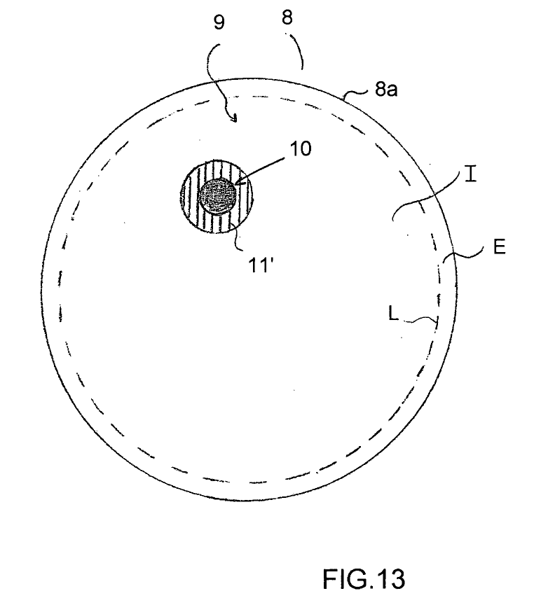

### 2D Embodiment/FIG. 13

In the embodiment of FIG. 13, and in contrast with all the embodiments of FIGS. 1 to 12, the passive elastic area (E) is obtained by using an elastic stop 11′ that is carried by the end-effector 10. The elastic stop 11′ is thus mobile with the end-effector 10. In this 2D hybrid device of FIG. 13, the elastic stop 11′ replaces the elastic torous 11 of the embodiment of FIGS. 5 to 9, and defines, in combination with the housing 8 of the device, an annular passive elastic area (E) [represented on FIG. 13 between a fictive dotted circular line (L) and the circular edge 8a of housing 8).

With the same spirit, the 1D hybrid device of FIGS. 1 to 4 could be also modified by replacing the washers 7 and springs 6 by an elastic stop carried by the end-effector 5. The 3D hybrid device of FIG. 12 could be modified by replacing the rigid sphere 19 by an elastic sphere and by replacing the elastic ovoid 18 by a rigid ovoid.

1-12. (canceled)

13. An absolute input device with passive force feedback comprising an end-effector that is mechanically connected to a support and that is mobile with relation to this support in a work area, wherein the work area is divided into at least two distinct adjacent areas: an isotonic area and a passive elastic area.

14. The one-dimensional input device according to claim 13, wherein the end-effector is guided in translation according to a unique axis of displacement and in that the work area is divided into three areas: one central isotonic area and two passive elastic areas positioned respectively at the two extremities of the central isotonic area.

15. The two-dimensional input device according to claim 13, wherein the mobile end-effector has two degrees of freedom.

16. The three-dimensional input device according to claim 13 wherein the mobile end-effector has three degrees of freedom.

17. The two-dimensional input device according to claim 15, wherein the work area is divided into two areas: one central isotonic area and one peripheral passive elastic area.

18. The three-dimensional input device according to claim 16, wherein the work area is divided into two areas: one central isotonic area and one peripheral passive elastic area.

19. The two-dimensional device according to claim 15, wherein the work area forms a disk.

20. The two-dimensional device according to claim 17, wherein the work area forms a disk.

21. The three-dimensional device according to claim 16, wherein the work area is spherical.

22. The three-dimensional device according to claim 18, wherein the work area is spherical.

23. The three-dimensional device according to claim 16, wherein the device comprises an arm whose free extremity forms the end-effector of the device, and on which arm is fixed a sphere that is mobile inside a hollow ovoid, either the sphere or the ovoid being elastic.

24. The three-dimensional device according to claim 18, wherein the device comprises an arm whose free extremity forms the end-effector of the device, and on which arm is fixed a sphere that is mobile inside a hollow ovoid, either the sphere or the ovoid being elastic.

25. The three-dimensional device according to claim 21, wherein the device comprises an arm whose free extremity forms the end-effector of the device, and on which arm is fixed a sphere that is mobile inside a hollow ovoid, either the sphere or the ovoid being elastic.

26. The input device according to claim 13, wherein a passive elastic area comprises at least one spring.

27. The input device according to claim 13, wherein a passive elastic area comprises an elastic stop filled with a fluid.

28. The input device according to claim 13, wherein a passive elastic area comprises an elastic stop made of an elastic material.

29. The input device according to claim 13, wherein the passive elastic area is obtained by using an elastic stop that is mobile with the end-effector.
